(19) United States
(12) Patent Application Publication
(10) Pub. No.: US 2013/0026113 A1
(43) Pub. Date: Jan. 31, 2013

(54) SERVER RACK WITH LOCKABLE SLIDE ASSEMBLY

(71) Applicants: CHEN-LU FAN, Tu-Cheng (TW); JING-CHAO LIANG, Shenzhen City (CN)

(72) Inventors: CHEN-LU FAN, Tu-Cheng (TW); JING-CHAO LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/483,890

(22) Filed: May 30, 2012

(30) Foreign Application Priority Data
Jul. 27, 2011 (CN) 201110212121.9

(51) Int. Cl. H05K 7/18; H05K 7/00

(52) U.S. Cl. 211/26; 248/298.1

(57) ABSTRACT

A slide assembly includes a slide, a fastener, and a latch. The slide includes a web and a flange substantially perpendicular to the web. The fastener is mounted on the flange. The fastener includes a first retaining portion and a second retaining portion. The first retaining portion is engaged with the locking hole. The latch is mounted on the web. The latch includes a locking member. The locking member includes a first locking portion and a second locking portion. The latch is resilient deformed from a first position to a second position. In the first position, the first retaining portion and the first locking portion are coupled to mount to a first bracket. In the second position, the second retaining portion and the second locking portion are coupled to mount to a second bracket.

### BACKGROUND

1. Technical Field

The present disclosure relates to server racks, especially to a server rack with a lockable slide assembly.

2. Description of Related Art

Computer network systems include many separate computer units or servers that are positioned and stacked relative to each other in a rack. The rack includes a plurality of support columns, where each computer server is secured to opposing slide assemblies attached to the columns. The slide assemblies allow the servers to be pulled away from the front of the rack so that each separate server can be serviced by technicians for various reasons, such as maintenance, replacement of computer cards, etc., while the server is still in operation.

Known slide assemblies generally include a stationary member having a front bracket and a rear bracket. The front bracket is rigidly secured to a front column of the rack, and the rear bracket is rigidly secured to a corresponding rear column of the rack. The inner most slidable member is secured to a sidewall of the server. When the technician pulls the server away from the rack, the slidable members slide relative to the stationary member allowing the server to be extended out of the rack.

The support columns include holes and the front and rear brackets include associated pins. The pins are inserted into the desired holes in the columns to align and hold the slide assembly. Various devices and techniques are known in the art to secure the slide assembly to the columns so that they are securely affixed thereto. These known techniques are sometimes complicated, requiring installation tools and the like to perform the mounting procedure. Additionally, certain techniques use loose hardware, such as screws and bolts that may be lost and are inconvenient to keep track of.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled, isometric view of an embodiment of a server rack assembled with a server.

FIG. 2 is an exploded, partial view of the server rack.

FIG. 3 is an enlarged view of a circled portion III of FIG. 2.

FIG. 4 is an assembled view of a slide assembly of the rack assembly of FIG. 2.

FIG. 5 is an enlarged view of a circled portion V of FIG. 1.

FIG. 6 is a partial, isometric view of the slide assembly in another working state in one embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

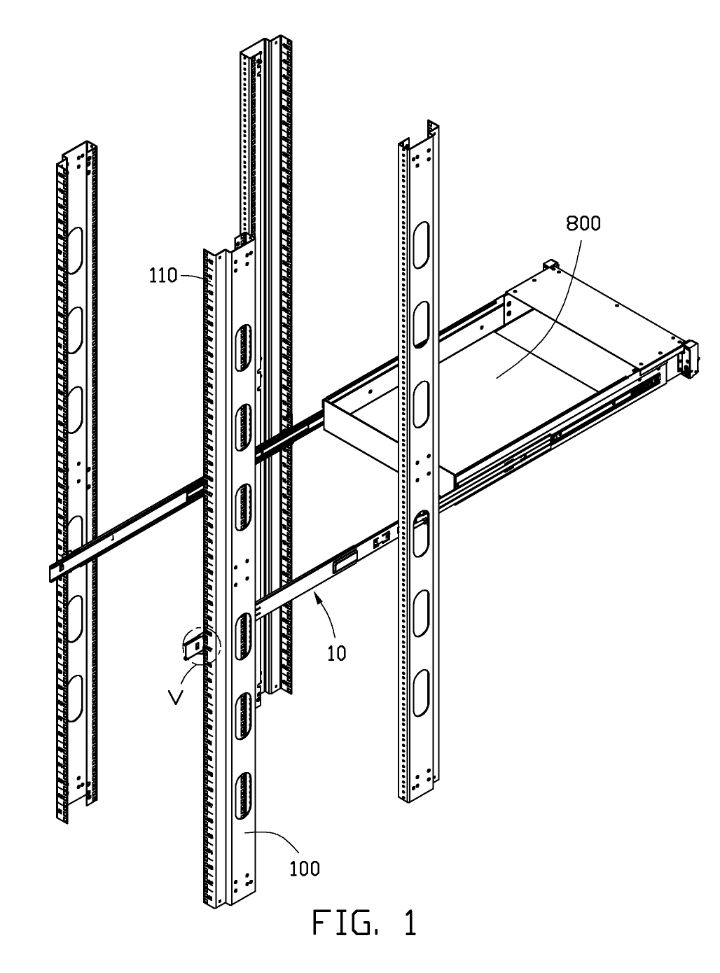

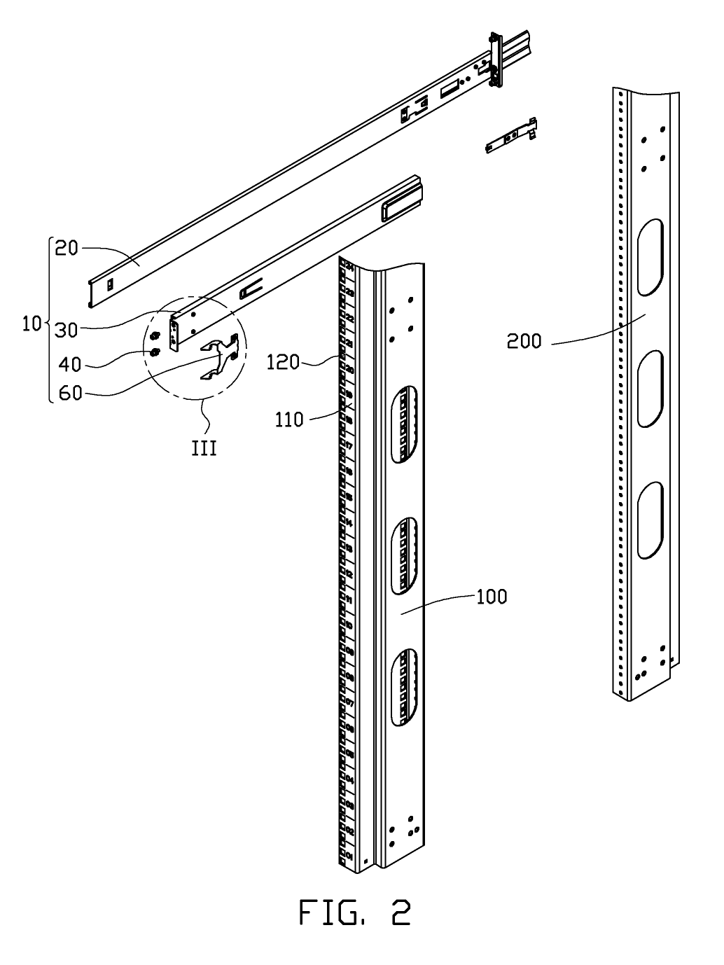

Referring to FIG. 1 and FIG. 2, one embodiment of a server rack includes at least one first bracket 100, at least one second bracket 200, and a pair of slide assemblies 10. Each slide assembly 10 is mounted on one first bracket 100 and one second bracket 200. The pair of the slide assembly 10 cooperatively mounts a server 800. Each first bracket 100 includes a side plate 110. A plurality of locking holes 120 are defined in the side plate 110 along a vertical direction. Each of the plurality of locking holes 120 may be round or square.

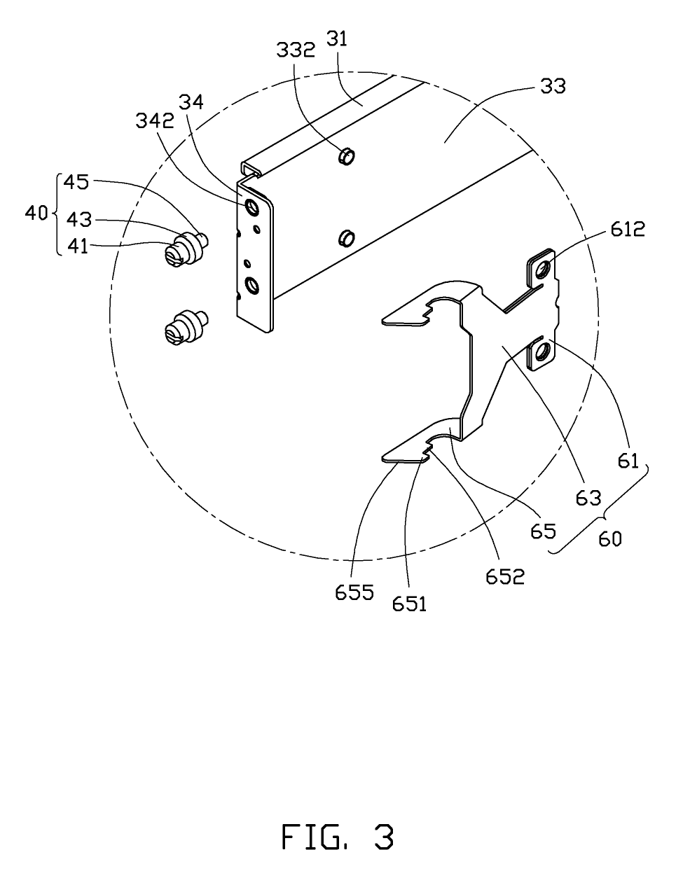

Referring to FIG. 2 and FIG. 3, the slide assembly 10 includes a first slide 20, a second slide 30, two fasteners 40, and a latch 60. The first slide 20 is telescopically mounted to the second slide 30. The second slide 30 includes a web 33, a pair of rims 31 located on opposite sides of the web 33, and a flange 34 located on a distal end of the web 33. Two posts 332 protrude from the web 33. Two retaining holes 342 are defined in the flange 34. The flange 34 is substantially perpendicular to the web 33.

Each of the fasteners 40 includes a first retaining portion 41, a second retaining portion 43, and a holding portion 45 corresponding to the retaining hole 342. The second retaining portion 43 is located between the first retaining portion 41 and the holding portion 45. At least one of the first retaining portion 41 and the second retaining portion 43 includes a circle outer edge or a square outer edge. A diameter of an outer edge of the first retaining portion 41 is smaller than a diameter of an outer edge of the second retaining portion 43. In one embodiment, both the first retaining portion 41 and the second retaining portion 43 have circle outer edge. The fastener 40 may include rubber.

In one embodiment, the latch 60 includes a mounting piece 61, a resilient connecting piece 63, and two locking pieces 65. The mounting piece 61 defines two mounting holes 612 corresponding to the two posts 332. The connecting piece 63 is substantially “Y” shaped. The two locking pieces 65 extrude from opposite sides of the connecting piece 63. Each of the locking pieces 65 includes a first locking portion 651, a second locking portion 652, and a guiding portion 655. The guiding portion 655 is step like. The guiding portion 655 is oblique relative to the side plate 110.

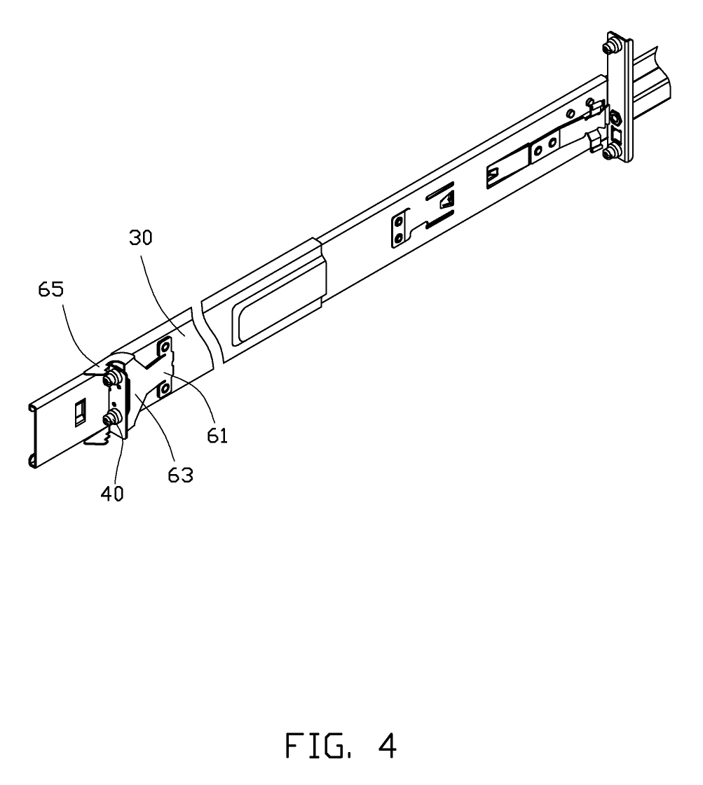

Referring to FIG. 4, in assembly of the slide assembly 10, the first slide 20 is telescopically mounted to the second slide 30. The fasteners 40 are mounted to the flange 34 through the retaining holes 342. The latch 60 is pivotably mounted on the web 33 with the posts 332 extending through the mounting holes 612 of the mounting piece 61. The latch 60 is located at an original state and the guiding portion 655 is slanted relative to the flange 34. The first locking portion 651 and the second locking portion 652 are located at the outer side of the flange 34.

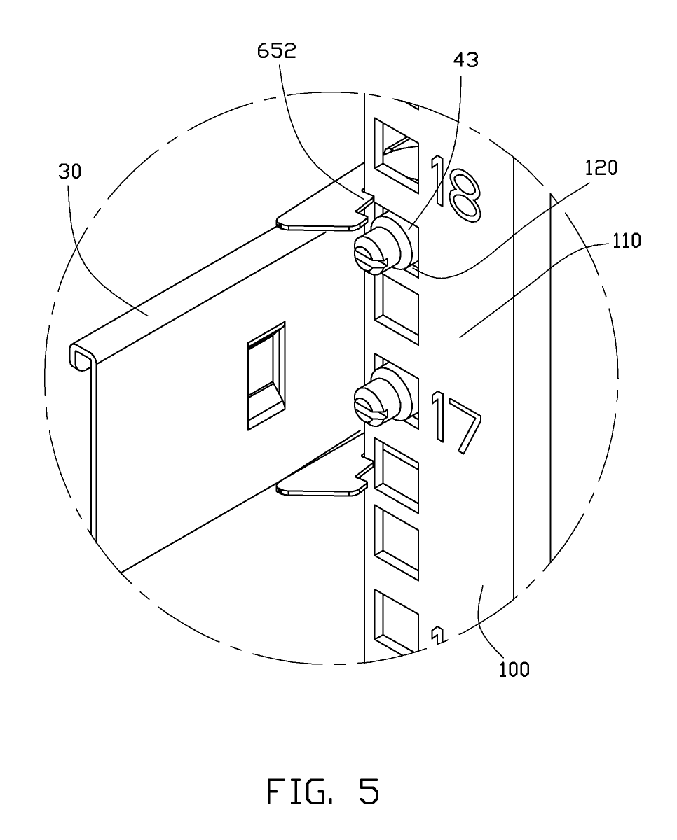

Referring to FIG. 5, when the slide assembly 10 is mounted to the first bracket 100. The second retaining portion 43 is engaged with the locking hole 120. The second locking portion 652 is clasped on an inner edge of the side plate 110.

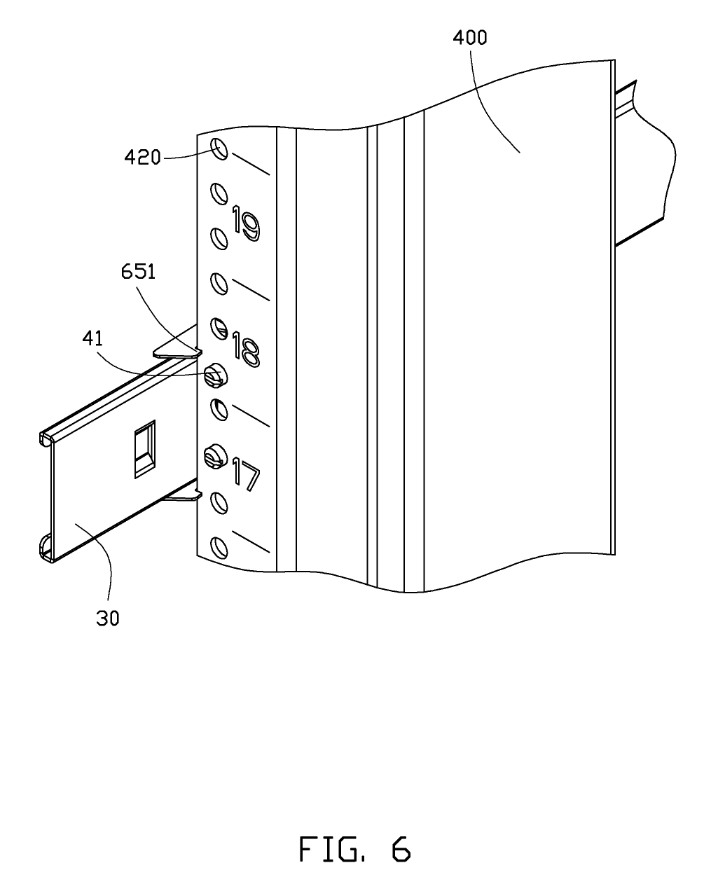

Referring to FIG. 6, the slide assembly 10 may be mounted to a third bracket 400 alternatively. The third bracket 400 includes a plurality of mounting holes 420. A diameter of each of the plurality of mounting holes 420 is smaller than a diameter of each of the plurality of locking holes 120. The first retaining portion 41 is engaged with the mounting hole 420. The first locking portion 651 is clasped on the third bracket 400.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A server rack comprising:
a first bracket comprising a side plate, and the side plate defining a first locking hole;
a slide assembly, comprising:
a slide comprising a web and a flange substantially perpendicular to the web, and the flange substantially parallel to the side plate;
a fastener mounted on the flange, the fastener comprising a first retaining portion, and the first retaining portion being engaged with the locking hole;
a latch pivotably mounted on the web, the latch comprising a locking member, the locking member comprising a first locking portion, and the first locking portion being clasped on the bracket.

2. The server rack of claim 1, wherein the fastener further comprising a second retaining portion to engage with a second locking hole defined in a second bracket, a diameter of the second locking hole is not equal to the first locking hole, and the locking member further comprises a second locking portion to lock the slide assembly coupled with the second retaining portion.

3. The server rack of claim 2, wherein the first retaining portion is located at a distal end of the fastener, and a diameter of an outer edge of the first retaining portion is smaller than a diameter of an outer edge of the second retaining portion.

4. The server rack of claim 3, wherein at least one of the first retaining portion and the second retaining portion includes a circled outer edge.

5. The server rack of claim 3, wherein at least one of the first retaining portion and the second retaining portion include a square outer edge.

6. The server rack of claim 2, wherein the first locking portion and the second locking portion are step like.

7. The server rack of claim 1, wherein the locking member is located in a first plane, which is substantially perpendicular to the side plate.

8. The server rack of claim 1, wherein the locking member further comprises a guiding portion, and the guiding portion is oblique with the side plate.

9. The server rack of claim 1, wherein the latch comprises a connecting plate, the locking member comprises two locking pieces, and the two locking pieces are located at opposite sides of the connecting plate.

10. A slide assembly, comprising:
a slide comprising a web and a flange substantially perpendicular to the web;
a fastener mounted on the flange, the fastener comprising a first retaining portion and a second retaining portion, and the first retaining portion being engaged with the locking hole;
a latch mounted on the web, the latch comprising a locking member, and the locking member comprising a first locking portion and a second locking portion;
wherein the latch is resilient deformed from a first position to a second position, in the first position, the first retaining portion and the first locking portion are coupled to mount to a first bracket; in the second position, and the second retaining portion and the second locking portion are coupled to mount to a second bracket.

11. The slide assembly of claim 10, wherein a diameter of the first locking portion is not equal to a diameter of the second locking portion.

12. The slide assembly of claim 11, wherein the first retaining portion is located at a distal end of the fastener, and a diameter of an outer edge of the first retaining portion is smaller than a diameter of an outer edge of the second retaining portion.

13. The slide assembly of claim 12, wherein at least one of the first retaining portion and the second retaining portion includes a circled outer edge.

14. The slide assembly of claim 12, wherein at least one of the first retaining portion and the second retaining portion include a square outer edge.

15. The slide assembly of claim 11, wherein the first locking portion and the second locking portion are step like.

16. The slide assembly of claim 10, wherein the locking member is located in a first plane, which is substantially perpendicular to flange.

17. The slide assembly of claim 10, wherein the locking member further comprises a guiding portion, and the guiding portion is oblique with the side plate.

18. The slide assembly of claim 10, wherein the latch comprises a connecting plate, the locking member comprises two locking pieces, and the two locking pieces are located at opposite sides of the connecting plate.
